(19) United States
(12) Patent Application Publication
(10) Pub. No.: US 2021/0099128 A1
(43) Pub. Date: Apr. 1, 2021

(54) RELAXATION OSCILLATOR CIRCUIT WITH PROCESS VARIATION COMPENSATION

(71) Applicant: MACRONIX INTERNATIONAL CO., LTD., HSINCHU (TW)

(72) Inventors: Shang-Chi YANG, Changhua (TW); June-Yi LI, Yunlin (TW)

(73) Assignee: MACRONIX INTERNATIONAL CO., LTD., HSINCHU (TW)

(21) Appl. No.: 16/842,068

(22) Filed: Apr. 7, 2020

Related U.S. Application Data
(60) Provisional application No. 62/909,183, filed on Oct. 1, 2019.

(51) Int. Cl. H03B 5/24; H03K 19/20

(52) U.S. Cl. CPC H03B 5/24; H03K 19/20

(57) ABSTRACT

An oscillator includes a charging circuit to charge and discharge a capacitive node, and a detector having a trigger point, and an input node operatively coupled to the capacitive node. The detector can comprise an inverter generating a detector output as a function of the trigger point and a voltage on the capacitive node, including means for reducing variation in the trigger point as a consequence of process variation a control circuit to alternately enable the charging circuit to charge the capacitive node and to discharge the capacitive node in response to changes in the detector output, and to provide an oscillator output signal.

### PRIORITY APPLICATION

This application claims the benefit of U.S. Provisional Patent Application No. 62/909,183 filed 1 Oct. 2019, which application is incorporated herein by reference.

### BACKGROUND

### Field

The present invention relates to relaxation oscillator circuitry, usable for generating digital clocks on integrated circuits, and technology to compensate for process variations.

### Description of Related Art

Relaxation oscillators comprise charging circuits that charge a capacitor. A detector is connected to the capacitor, and turns on a circuit to discharge the capacitor when the detector is triggered. The detector output which causes the switching between charge and discharge cycles can be converted to a clock signal having a period that is a function of the time required after each discharge cycle, to charge the capacitor to a trigger point on the detector.

The trigger point is a circuit parameter that can vary with process variations arising in manufacture, and therefore may result in variations in the period of the clock signal.

Trigger points can be evaluated using process corner analysis that relates to variation in, for example, n-type mobility and p-type mobility in the integrated circuit. One explanation of process corners is found in Wikipedia, in which the article reads, “There are therefore five possible corners: typical-typical (TT) (not really a corner of an n vs. p mobility graph, but called a corner, anyway), fast-fast (FF), slow-slow (SS), fast-slow (FS), and slow-fast (SF). The first three corners (TT, FF, SS) are called even corners, because both types of devices are affected evenly, and generally do not adversely affect the logical correctness of the circuit. The resulting devices can function at slower or faster clock frequencies, and are often binned as such. The last two corners (FS, SF) are called “skewed” corners, and are cause for concern. This is because one type of FET will switch much faster than the other, and this form of imbalanced switching can cause one edge of the output to have much less slew than the other edge. Latching devices may then record incorrect values in the logic chain.” Wikipedia contributors. (2019, Apr. 3). Process corners. In Wikipedia, The Free Encyclopedia. Retrieved 19:18, Mar. 13, 2020, from https://en.wikipedia.org/w/index.php?title=Process_corners &oldid=890740894.

It is desirable to provide a circuitry for a relaxation oscillator that is more stable over variations in process.

### BRIEF DESCRIPTION OF THE DRAWINGS

FIG. 1 is a diagram of a prior art relaxation oscillator in which the detectors are implemented using inverters.

FIG. 2 is a graph showing variation in trigger points for a typical inverter on process corners.

FIG. 3 is a timing diagram of the prior art relaxation oscillator, illustrating variations in clock period as a result of variations in trigger points for process corners.

FIG. 4 is a diagram of a relaxation oscillator including detectors that comprise means for reducing variation in the trigger point as a consequence of process variation.

FIG. 5 is a circuit diagram of an inverter usable as a detector in a circuit like that of FIG. 4.

FIG. 6 is a graph showing variations in trigger points for an inverter like that of FIG. 4 on process corners.

FIG. 7 shows a comparison of the plots of FIG. 2 and FIG. 6.

FIG. 8 illustrates results of process corner simulation of a relaxation oscillator with a circuit for trigger point variation compensation like that of FIG. 4, compared with a relaxation oscillator without such compensation.

FIG. 9 is a circuit diagram of an alternative inverter usable as a detector in a circuit like that of FIG. 4.

### DETAILED DESCRIPTION

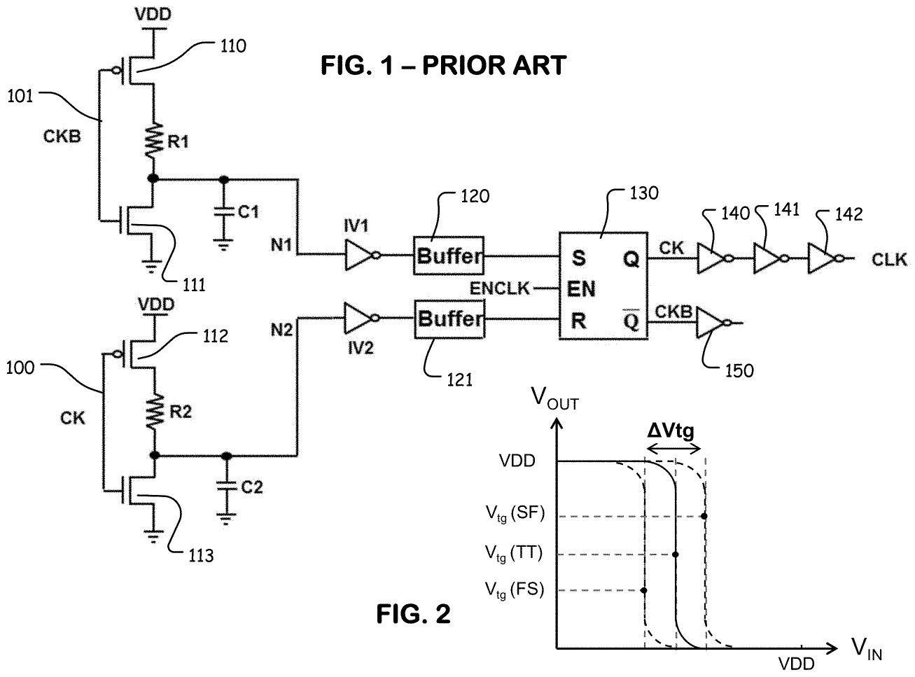

A detailed description of embodiments of the present invention is provided with reference to the FIGS. 1-9.

FIG. 1 illustrates an example of a relaxation oscillator. The relaxation oscillator includes a first charging circuit that includes p-channel transistor 110, resistor R1 and n-channel transistor 111 connected in series between a supply potential VDD and a reference node connected to VSS, where VSS can be a DC ground. In other embodiments, VSS can be an AC ground or other DC voltage reference. The inputs to transistors 110 and 111 are connected to line 101 carrying the signal CKB. The drain of transistor 111 is connected to a capacitive node N1. Also a capacitor C1 is connected between the capacitive node N1 and the reference code. The capacitive node N1 is connected to an input of a detector, implemented in this example using an inverter IV1. Also, the relaxation oscillator includes a second charging circuit that includes p-channel transistor 112, resistor R2 and n-channel transistor 113, connected in series between a supply potential VDD and a reference node connected to VSS. The inputs to transistors 112 and 113 are connected to line 100 carrying the control signal CK. The drain of transistor 113 is connected to a capacitive node N2. Also a capacitor C2 is connected between the capacitive node N2 and the reference node. The capacitive node N2 is connected to an input of a detector, implemented in this example using an inverter IV2.

A control circuit including buffer 120, buffer 121, SR latch 130, inverters 140-142, and inverter 150 is coupled to the outputs of the inverters IV1 and IV2. In this example, the inverter IV1 has an output connected to the buffer 120, the output of which is in turn connected to the S input of the SR latch 130. Also, the inverter IV2 has an output connected to the buffer 121, the output of which is in turn connected to the R input of the SR latch 130. The Q output of the SR latch is the control signal CK fed back to line 100 at the input of the second charging circuit. The/Q output of the SR latch 130 is the control signal CKB fed back to the line 101 at the input of the first charging circuit. The control signal CK is applied through the string of inverters 140-142, which drive output clock signal CLK (which due to the odd number inverter string is inverted CK). Also, the control signal CKB is applied through the inverter 150, and is usable as an inverted output clock.

The inverters IV1 and IV2 in this prior art example have a transfer function like that illustrated in FIG. 2, in which the trigger points vary significantly with process corner. FIG. 2 is a plot of the transfer function of the output voltage V_{OUT} of the inverter versus the input voltage V_{IN} of the inverter. As can be seen, and inverter usually has a very steep high to low transition from VDD and VSS as the input voltage V_{IN} sweeps upwardly toward VDD and reaches the trigger point. The trigger point, as the term is used herein for an inverter, is the input voltage level at which the output voltage V_{OUT} equals V_{IN} during the transition. The plot in FIG. 2 illustrates that the FS process corner has a relatively low Vtg (FS), the TT process corner has an intermediate Vtg (TT) and the SF process corner has a relatively high Vtg (SF). The time required for the charging circuits to reach the trigger point Vtg (FS) of the inverters IV1, IV2 can be significantly shorter than the time required for the charging circuits to reach trigger point Vtg (TT). Also, the time required for the charging circuit to reach the trigger point Vtg (SF) of the inverters IV1, IV2 can be significantly longer than the time required for the charging circuits to reach the trigger point Vtg (TT). This variation is illustrated in the plot as a difference ΔVtg across process corners in trigger point voltage, which corresponds to substantial variations in clock period and frequency.

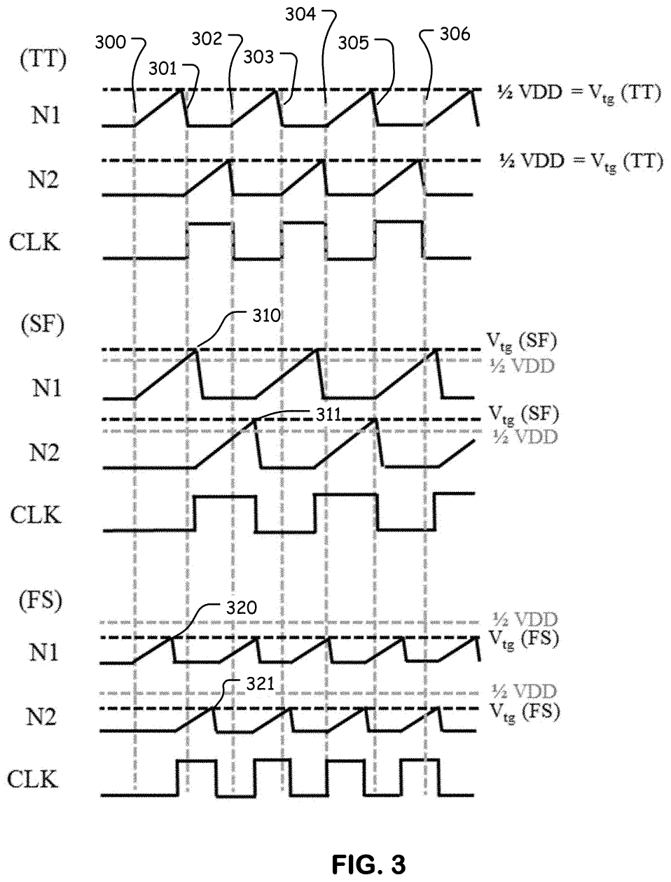

The effect on clock period which can be mitigated by limiting variations in trigger point is illustrated in the timing chart of FIG. 3. FIG. 3 plots the voltage on the capacitive nodes N1 and N2 versus the output clock CLK for the TT, SF and FS process corners. Looking at the TT process corner in the upper part of the chart, the clock CLK starts at a low value enabling the charging circuit at time 300 to charge up node N1. The first charging circuit charges the voltage on node N1 up to the trigger point Vtg (TT), which can be for example ½ VDD. When the inverter IV1 switches at time 301, CLK will transition high and cause the first charging circuit to discharge node N1. Also, on the transition of CLK at time 301, the second charging circuit charges the voltage on node N2 up to the trigger point Vtg (TT). When the inverter IV2 switches at time 302, CLK will transition low and cause the second charging circuit to discharge node N2, and the first charging circuit to begin charging node N1. The node N1 is charged between times 302 and 303, node N2 is charged between times 303 and 304, node N1 is charged between times 304 and 305, node N2 is charged between times 305 and 306, and so on.

Looking at the SF process corner in the middle of the chart, the trigger point Vtg (SF) is higher (e.g. more than ½ VDD) than the trigger point Vtg (TT). Thus, the time interval starting at time 300 until the node N1 reaches the trigger point Vtg (SF) at time 310 is longer than the time between times 300 and 301. Likewise, the time interval between time 301 and the time 311, at which node N2 reaches the trigger point Vtg (SF), is longer than the time between times 301 and 302. This results in a longer clock period and a slower clock frequency at process corner SF compared to process corner TT.

Looking at the FS process corner in the bottom of the chart, the trigger point Vtg (FS) is lower (e.g. less than ½ VDD) than the trigger point Vtg (TT). Thus, the time interval starting at time 300 until the node N1 reaches the trigger point Vtg (FS) at time 320 is shorter than the time between times 300 and 301. Likewise, the time interval between time 301 and the time 321, at which node N2 reaches the trigger point Vtg (FS), is shorter than the time between times 301 and 302. This results in a shorter clock period and a faster clock frequency at process corner FS compared to process corner TT.

Thus, as illustrated in FIG. 3, a relaxation oscillator like that of FIG. 1 can have a clock period within a wide range due to process variations. Technology described herein provides a means to mitigate variations in trigger point, and consequential variations in clock periods, that arise from process variations in manufacture.

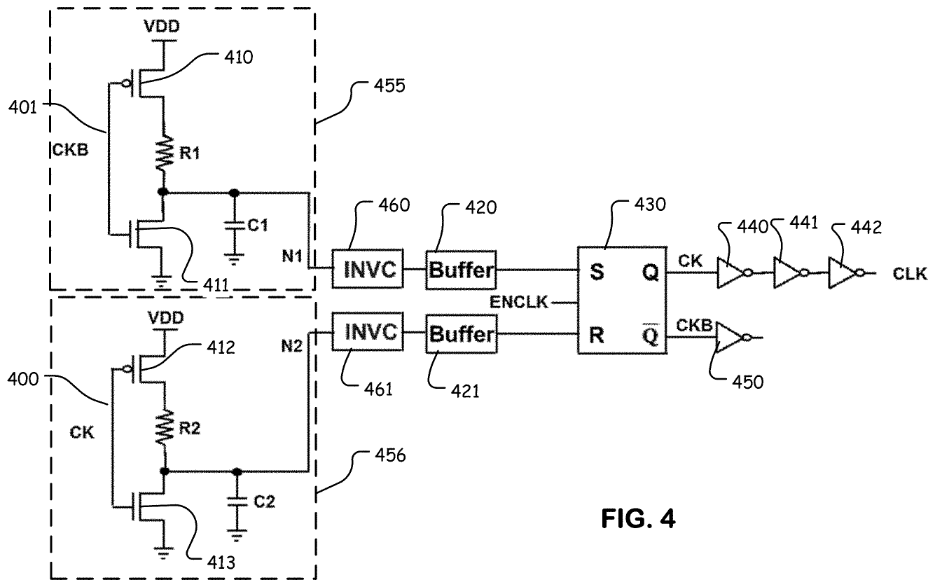

FIG. 4 is a diagram of an embodiment of a relaxation oscillator in which the detectors comprise means for reducing variation in the trigger point as a consequence of process variation, and thereby provide for a more stable clock period over process variations.

The relaxation oscillator of FIG. 4 includes a first charging circuit 455 that includes p-channel transistor 410, resistor R1 and n-channel transistor 411 connected in series between a supply potential VDD and a reference node connected to VSS, where VSS can be a DC ground. In other embodiments VSS can be an AC ground or other DC voltage reference. The inputs to transistors 410 and 411 are connected to line 401 carrying the signal CKB. The drain of transistor 411 is connected to a capacitive node N1. Also a capacitor C1 is connected between the capacitive node N1 and the reference code. The capacitive node N1 is connected to an input of a detector, implemented in this example using detector 460 including comprising an inverter INVC including a process variation compensation circuit. Also, the relaxation oscillator includes a second charging circuit 456 that includes p-channel transistor 412, resistor R2 and n-channel transistor 413 connected in series between a supply potential VDD and a reference node connected to VSS. The inputs to transistors 412 and 413 are connected to line 400 carrying the control signal CK. The drain of transistor 413 is connected to a capacitive node N2. Also a capacitor C2 is connected between the capacitive node N2 and the reference code. The capacitive node N2 is connected to an input of a detector, implemented in this example detector 461 including comprising an inverter INVC including a process variation compensation circuit.

A control circuit including buffer 420, buffer 421, SR latch 430, inverters 440-442, and inverter 450, is coupled to the outputs of the detectors 460 and 461. In this example, the detector 460 has an output connected to the buffer 420, the output of which is in turn connected to the S input of the SR latch 430. Also, the detector 461 has an output connected to the buffer 421, the output of which is in turn connected to the R input of the SR latch 430. The Q output of the SR latch is the control signal CK fed back to line 400 at the input of the second charging circuit 456. The /Q output of the SR latch 430 is the control signal CKB fed back to the line 401 at the input of the first charging circuit 455. The control signal CK is applied through the string of inverters 440-442, which drive output clock signal CLK (which due to the odd number inverter string is inverted CK). Also, the control signal CKB is applied through the inverter 450, and is usable as an inverted output clock.

The detector 460 is a first buffer in a series of buffers, including detector 460 and buffer 420 in this example, which can reduce switching level variation and provide tolerance to input noise, improving the stability of the oscillator output time periods.

Because the detectors 460 and 461 include process variation compensation circuits, the trigger points of the detectors vary over a smaller range due to process variations. As a result, the clock periods and clock frequencies of a lot of integrated circuits including the relaxation oscillators are more stable across the lot.

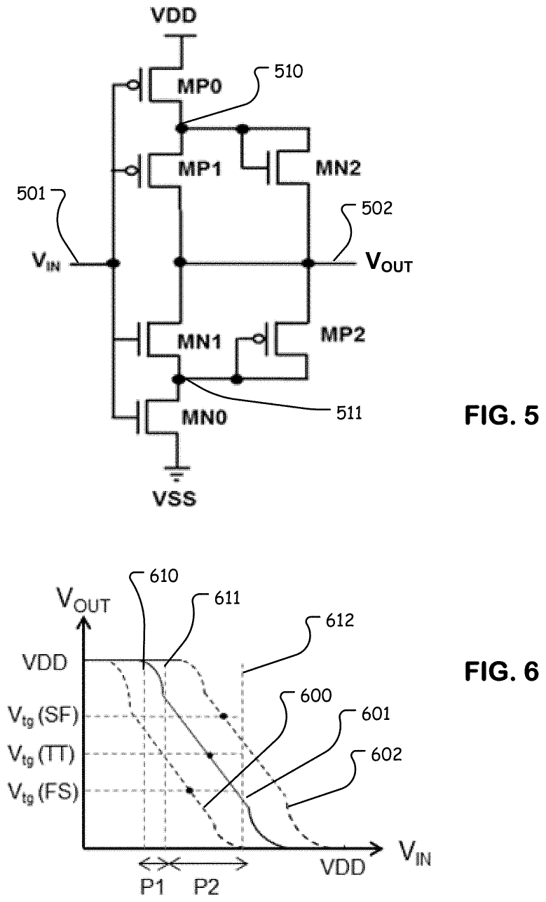

FIG. 5 illustrates an embodiment of an inverter including means for reducing variation in the trigger point of the inverter as a consequence of process variation, which can be used as the detectors 460, 461 of FIG. 4.

The inverter of FIG. 5 has an input node 501 which receives an input voltage V_{IN}, such as the voltage on node N1 or on node N2 in the circuit of FIG. 4. The input voltage is applied to the gates of first and second PMOS transistors MP0 and MP1, and to the gates of first and second NMOS transistors MN0 and MN1.

The first NMOS transistor (MN0) and the second NMOS transistor (MN1) are connected in series between a reference voltage terminal VSS and an output node 502, and their gates are connected to said input node 501.

The first PMOS transistor (MP0) and the second PMOS transistor (MP1) are connected in series between a supply voltage terminal VDD and the output node 502, and their gates connected to said input node 501.

A first resistive element connected between said output node 502 at with an output V_{OUT} is generated and a node 510 between MP0 and MP1, in this example at the drain of MP0 and the source of MP1. In this example, the first resistive element comprises a diode connected NMOS transistor MN2, having its gate and drain connected to the node 510 between the transistors MP0 and MP1, and its source connected to the output node 502.

A second resistive element is connected between said output node 502 and a node 511 between MN0 and MN1, in this example at the drain of MN0 and the source of MN1. In this example, the first resistive element comprises a diode connected PMOS transistor MP2, having its gate and drain connected to the node 511 between the transistors MN0 and MN1, and its source connected to the output node 502.

As a result of the operation of the first and second resistive elements, the gain of the inverter of FIG. 6 is reduced, resulting in a transition of the V_{IN} versus V_{OUT} plot that is less steep than occurs in a higher gain circuit.

Operation of the inverter of FIG. 5 can be described with reference to the transfer plot of FIG. 6. In FIG. 6, the transfer plot for the FS corner is shown on plot 600, the transfer plot for the TT corner is shown on plot 601, and the transfer plot for the SF corner is shown on plot 602. Operation of the circuit can be described with reference to three phases (P1, P2 and the phase P3 after P2) in the plot for the TT corner on plot 601, as the input voltage V_{IN} increases from VSS to VDD.

During the first phase P1, as V_{IN} begins to increase the output voltage V_{OUT} falls rapidly between times 610 and 611. During this time interval, the transistors are biased as follows:

Phase P1:

| | Operating |
|---|---|
| Transistor | Region |
| MN0 | Saturation |
| MN1 | Cutoff |
| MN2 | Cutoff |
| MP0 | Linear |
| MP1 | Linear |
| MP2 | Saturation |

In this phase P1, as V_{IN} begins to turn on MN0 before MN1 turns on, and the diode connected MP2 begins to conduct through MN0 to VSS, discharging the output voltage V_{OUT}, the voltage of which begins to drop rapidly due to the pulldown current. MN2 remains off because V_{OUT} is higher than V_{IN} less the threshold of MP0 operating in the linear region.

Phase P2:

| | Operating |
|---|---|
| Transistor | Region |
| MN0 | Linear |
| MN1 | Saturation |
| MN2 | Saturation |
| MP0 | Linear |
| MP1 | Saturation |
| MP2 | Saturation |

In this phase P2, between times 611 and 612, V_{IN} gets high enough to turn on MN1 adding increased pulldown current, MN2 turns on as V_{OUT} falls, which generates current that opposes the pulldown current in this part of the transition causing the slope of the transfer plot to become less steep. However, the pulldown current remains stronger than the pull up current because MP0 is operating relatively weakly in the linear range.

Phase P3:

| | Operating |
|---|---|
| Transistor | Region |
| MN0 | Linear |
| MN1 | Linear |
| MN2 | Saturation |
| MP0 | Cutoff |
| MP1 | Cutoff |
| MP2 | Cutoff |

In this phase P3, after time 612 until the transition is over, V_{IN} gets high enough to cut off MP0 and MP1, blocking the opposing current through MN2. Also, as V_{OUT} falls due to pull down current through MN1 and MN0, the diode connected MP2 cuts off.

As the input voltage sweeps in this example, the compensated detector INVC output voltage change is less steep than a conventional inverter. A small signal model for a conventional inverter can be characterized as: Av=(gₘₚ₁+gₘₙ₁)(roₘₚ₁//roₘₙ₁). A small signal model for a compensated inverter INVC as described herein can be characterized in a generalized sense as: Av=(gₘₚ₁+gₘₙ₁)×(roₘₚ₁//roₘₙ₁)//(1/gmₘₙ₂//1/gmₘₚ₂). Because of resistive elements MN2 and MP2, the gain of the compensated inverter is smaller than a conventional inverter.

The PMOS and NMOS transistors in the circuit of FIG. 5, can be implemented using other types of p-channel and n-channel transistors in other embodiments.

Also shown in FIG. 6, the transfer plots for the FS and SF transitions are illustrated. The trigger points at which V_{OUT} equals V_{IN} on each of the plots 600, 601, 602 is indicated for the process corners. Although the detector of FIG. 5 operates in similar phases at the process corners, the trigger points have significantly different levels. However, the variation in trigger point is less over process variation as a result of the circuitry of FIG. 5, than in the example plotted in FIG. 2.

In the embodiment of FIG. 5, the means for reducing variation in the trigger point as a consequence of process variation comprises a circuit that opposes changes in the detector output during a part of a transition (phase 2) of an input voltage on the input node of the detector.

In the embodiment of FIG. 5, the means for reducing variation in the trigger point as a consequence of process variation comprises a circuit to provide current to enhance the pull down current during a first part (phase P1) of the transition and to oppose the pull down current during a second part (phase P2) of the transition.

In the embodiment of FIG. 4, the detector can be an inverter like that of FIG. 5, having a trigger point, and an input node operatively coupled to the capacitive node, generating an inverter output on an output node as a function of the trigger point and a voltage on the capacitive node, the inverter including a circuit to provide pull down current on the inverter output in response to a transition of an input voltage on the input node above the trigger point, and a circuit to provide current to oppose the pull down current during the transition.

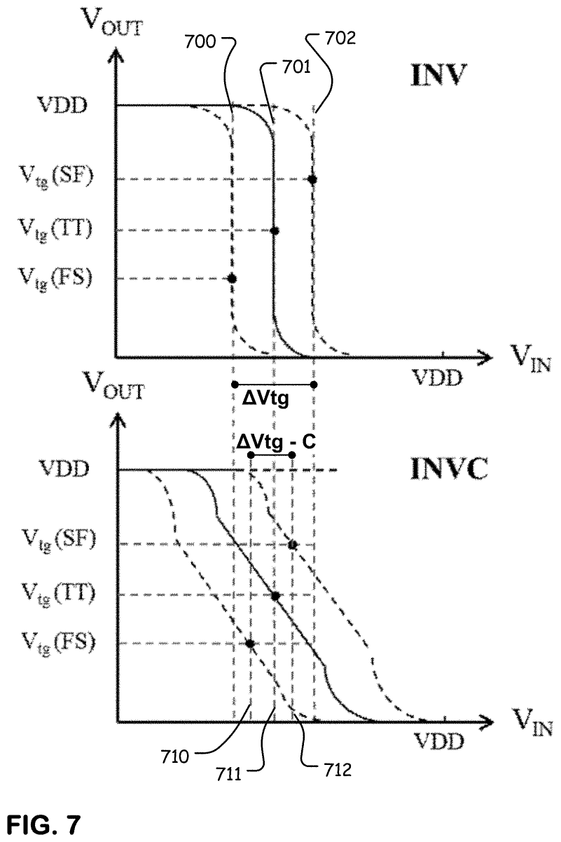

FIG. 7 provides a comparison of the plot of FIG. 2 and the plot of FIG. 6. As can be seen, the trigger points in the plot of FIG. 2 for a typical inverter occur at V_{IN} at levels 700, 701, 702 for the process corners FS, TT and SF, respectively. The difference ΔVtg between level 700 and 702 is relatively large in a circuit without compensation for process variation. For comparison, the trigger point in the plot of FIG. 6 for the inverter with compensation as described herein, occurs at V_{IN} levels 710, 711 and 712. The difference ΔVtg-C for the inverted compensation between level 710 and 712 is smaller than ΔVtg.

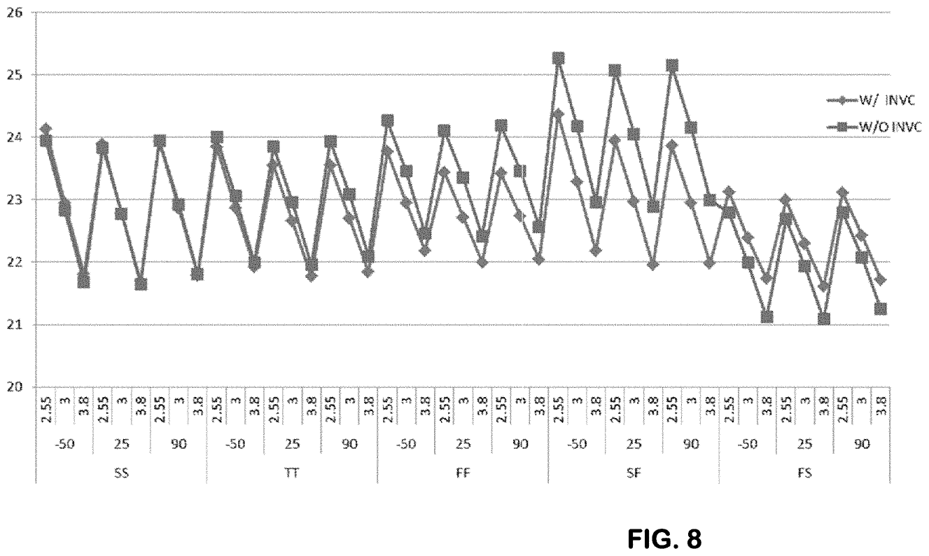

FIG. 8 illustrates the effect of this improvement on variations in the clock period for a relaxation oscillator like that of FIG. 4. FIG. 8 plots the process corners SS, TT, FF, SF and FS in three temperature ranges −50° C., 25° C. and 90° C., for an inverter without compensation (square points) and an inverter with compensation (diamond points) as described herein. For the SS, TT and FF process corners, the variation over temperature for the output clock period remains similar for the inverter without compensation and the inverter with compensation. However, for the critical process corners SF and FS, it is seen that the variation in clock period over temperature is significantly more stable for the inverter with compensation, than for the inverter without.

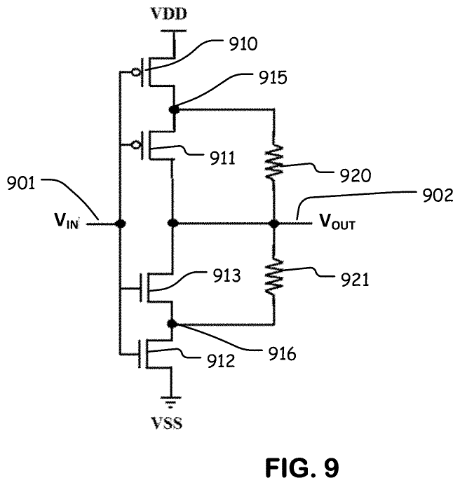

FIG. 9 illustrates an alternative inverter circuit with compensation. FIG. 9 illustrates an embodiment of an inverter including means for reducing variation in the trigger point of the inverter as a consequence of process variation, which can be used as the detectors 460, 461 of FIG. 4.

The inverter of FIG. 9 has an input node 901 which receives an input voltage V_{IN}, such as the voltage on node N1 or on node N2 in the circuit of FIG. 4. The input voltage is applied to node 901 connected to the gates of first and second PMOS transistors 910 and 911, and to the gates of first and second NMOS transistors 912 and 913.

The first NMOS transistor 912 and the second NMOS transistor 913 are connected in series between a reference voltage terminal VSS and an output node 902 at with the output voltage V_{OUT} is generated, and their gates connected to said input node.

The first PMOS transistor 910 and the second PMOS transistor 911 are connected in series between a supply voltage terminal VDD and the output node 902, and their gates connected to said input node 901.

A first resistive element is connected between said output node 902 and a node 915 between the first and second PMOS transistors 910 and 911, in this example at the drain of transistor 910 and the source of transistor 911. In this example, the first resistive element comprises a resistor 920, having a terminal connected to the node 915 between the first and second PMOS transistors 910 and 911, and a terminal connected to the output node 902.

A second resistive element is connected between said output node 902 and a node 916 between the first and second NMOS transistors 912 and 913, in this example at the drain of transistor 912 and the source of transistor 913. In this example, the first resistive element comprises a resistor 921, having a terminal connected to the node 916 between the first and second NMOS transistors 912 and 913, and a terminal connected to the output node 902.

The circuit of FIG. 9 operates in a manner like that of the circuit of FIG. 6, including means for reducing variation in the trigger point as a consequence of process variation. In the embodiment of FIG. 9, the means for reducing variation in the trigger point, as a consequence of process variation, comprises a circuit that opposes changes in the detector output during a part of a transition of an input voltage on the input node of the detector.

In the embodiment of FIG. 9, the means for reducing variation in the trigger point as a consequence of process variation comprises a circuit to provide current to enhance the pull down current during a first part of the transition and to oppose the pull down current during a second part of the transition.

In the embodiment of FIG. 4, the detector can be an inverter like that of FIG. 9, having a trigger point and an input node operatively coupled to the capacitive node, generating an inverter output on an output node as a function of the trigger point and a voltage on the capacitive node, the inverter including a circuit to provide pull down current on the inverter output in response to a transition of an input voltage on the input node above the trigger point, and a circuit to provide current to oppose the pull down current during the transition.

An inverter is described herein that includes devices (e.g., MP2, MN2, 920, 921) for providing pull up and pull down current, having the ability to compensate for process variation to maintain a more stable trigger point.

An inverter as described herein, with the ability to compensate for process variation to maintain a stable trigger point, can be used as a detector for all variety of RC delay circuits, in addition to the charging circuits described herein of a relaxation oscillator.

Examples of inverter circuits are described herein that use MOSFET transistors as resistive elements to compensate for input switching level variations that are caused by process variations.

An RC delay-based relaxation oscillator including an inverter trigger point variation compensation circuit is described that can achieve a stable clock period over variations in process and temperature. Use of the inverter trigger point variation compensation circuit in a first stage of a series of buffers can reduce the switching level variation, and provide great tolerance to input noise, resulting in improved stability of the oscillator time periods.

While the present technology is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the disclosure and the scope of the following claims.

What is claimed is:

1. An oscillator, comprising:
a charging circuit to charge and discharge a capacitive node;
a detector having a trigger point, and an input node operatively coupled to the capacitive node, generating a detector output as a function of the trigger point and a voltage on the capacitive node, including means for reducing variation in the trigger point as a consequence of process variation; and
a control circuit to alternately enable the charging circuit to charge the capacitive node and to discharge the capacitive node in response to changes in the detector output, and to provide an oscillator output signal.

2. The oscillator of claim 1, wherein the means for reducing variation comprises a circuit that opposes changes in the detector output during a part of a transition of an input voltage on the input node of the detector.

3. The oscillator of claim 1, wherein the detector comprises an inverter including a circuit to provide pull down current on the detector output in response to a transition of an input voltage on the input node above the trigger point, and the means for reducing variation in the trigger point comprises a circuit to provide current to enhance the pull down current during a first part of the transition and to oppose the pull down current during a second part of the transition.

4. The oscillator of claim 3, wherein the circuit to provide current to oppose the pull down current comprises a resistive circuit active during the transition.

5. The oscillator of claim 3, wherein the circuit to provide current to oppose the pull down current comprises a transistor configured to turn on during the transition.

6. The oscillator of claim 1, including:
a second charging circuit to charge and discharge a second capacitive node;
a second detector having a trigger point, and an input node operatively coupled to the second capacitive node, generating a second detector output as a function of the trigger point and a voltage on the second capacitive node, including means for reducing variation in the trigger point as a consequence of process variation; and
wherein the control circuit includes circuits to alternately enable the second charging circuit to charge the second capacitive node and to discharge the second capacitive node in response to changes in the second detector output.

7. An oscillator, comprising:
a charging circuit to charge and discharge a capacitive node;
an inverter having a trigger point, and an input node operatively coupled to the capacitive node, generating an inverter output on an output node as a function of the trigger point and a voltage on the capacitive node, the inverter including a circuit to provide pull down current on the inverter output in response to a transition of an input voltage on the input node above the trigger point, and a circuit to provide current to oppose the pull down current during the transition; and
a control circuit to alternately enable the charging circuit to charge the capacitive node and to discharge the capacitive node in response to changes in the inverter output on the output node, and to provide an oscillator output signal.

8. The oscillator of claim 7, wherein the circuit to provide current to oppose the pull down current comprises a resistive circuit active during the transition.

9. The oscillator of claim 7, wherein the circuit to provide current to oppose the pull down current comprises a transistor configured to turn on during the transition.

10. The oscillator of claim 7, including a circuit to enhance the pull down current during a first portion of the transition, wherein the circuit to oppose the pull down current is weaker than the circuit to enhance the pull down current during the first part of the transition, and is stronger during a second portion of the transition.

11. The oscillator of claim 7, wherein the inverter comprises:
a first NMOS transistor (MN0) and a second NMOS transistor (MN1) in series between a reference voltage terminal and the output node, wherein the first and second NMOS transistors have gates connected to said input node;
a first PMOS transistor (MP0) and a second PMOS transistor (MP1) in series between a supply voltage terminal and the output node, wherein the first and second PMOS transistors have gates connected to said input node; and
a first resistive element connected between said output node and a node between the first and second PMOS transistors; and
a second resistive element connected between said output node and a node between the first and second NMOS transistors.

12. The inverter of claim 11, wherein the first resistive element comprises a diode-connected NMOS, and the second resistive element comprises a diode-connected PMOS.

13. The oscillator of claim 7, including:
a second charging circuit to charge and discharge a second capacitive node;
a second inverter having a trigger point, and an input node operatively coupled to the second capacitive node, generating an inverter output on an output node as a function of the trigger point and a voltage on the second capacitive node, the second inverter including a circuit to provide pull down current on the inverter output in response to a transition of an input voltage on the input node above the trigger point, and a circuit to provide current to oppose the pull down current during the transition; and
wherein the control circuit includes circuits to alternately enable the second charging circuit to charge the second capacitive node and to discharge the second capacitive node in response to changes in the second inverter output.

14. An inverter comprising:
an input node and an output node;
a first NMOS transistor (MN1) and a second NMOS transistor (MN0) in series between a reference voltage terminal and the output node, wherein the first and second NMOS transistors have gates connected to said input node;
a first PMOS transistor (MP1) and a second PMOS transistor (MP0) in series between a supply voltage terminal and the output node, wherein the first and second PMOS transistors have gates connected to said input node;
a first resistive element connected between said output node and a node between the first and second PMOS transistors; and
a second resistive element connected between said output node and a node between the first and second NMOS transistors.

15. The inverter of claim 14, wherein the first resistive element comprises a diode-connected NMOS, and the second resistive element comprises a diode-connected PMOS.
